(19) United States
(12) Patent Application Publication
(10) Pub. No.: US 2025/0089355 A1
(43) Pub. Date: Mar. 13, 2025

(54) MULTI-THRESHOLD VOLTAGE INTEGRATION SCHEME FOR COMPLEMENTARY FIELD-EFFECT TRANSISTORS

(71) Applicant: Applied Materials, Inc., Santa Clara, CA (US)

(72) Inventors: San-Kuei Lin, Los Gatos, CA (US); Pradeep K. Subrahmanyan, Los Gatos, CA (US)

(73) Assignee: Applied Materials, Inc., Santa Clara, CA (US)

(21) Appl. No.: 18/824,195

(22) Filed: Sep. 4, 2024

Related U.S. Application Data
(60) Provisional application No. 63/537,005, filed on Sep. 7, 2023.
(60) Provisional application No. 63/537,056, filed on Sep. 7, 2023.

(51) Int. Cl. H01L 27/092; H01L 21/8238; H01L 29/06; H01L 29/10; H01L 29/423; H01L 29/66; H01L 29/775; H01L 29/786

(52) U.S. Cl. CPC H10D 84/85; H10D 30/014; H10D 30/43; H10D 30/6735; H10D 30/6757; H10D 30/751; H10D 62/115; H10D 62/121; H10D 84/0167; H10D 84/038

(57) ABSTRACT

Methods of manufacturing electronic devices are described. Embodiments of the present disclosure advantageously provide methods of manufacturing electronic devices, e.g., complementary field-effect transistors (CFETs) that meet reduced thickness, reduced leakage, lower thermal budget, and Vₜ requirements (including multi-Vₜ), and have improved device performance and reliability. Some embodiments of the methods include conventional dipole engineering techniques such as dipole first processes and/or dipole last processes without the need for repairing the interfacial layer after treatment (in dipole first processes) or repairing the high-κ dielectric layer after the annealing process (in dipole last processes).

### CROSS-REFERENCE TO RELATED APPLICATIONS

This application claims priority to U.S. Provisional Application No. 63/537,005, filed Sep. 7, 2023, and to U.S. Provisional Application No. 63/537,056, filed Sep. 7, 2023, the entire disclosures of which are hereby incorporated by reference herein.

### TECHNICAL FIELD

Embodiments of the present disclosure pertain to the field of electronic device manufacturing, and in particular, to transistors. More particularly, embodiments of the disclosure are directed to complementary field-effect transistors (CFETs) and methods of manufacturing CFETs.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Transistors are circuit components or elements that are often formed on semiconductor devices. Many transistors may be formed on a semiconductor device in addition to capacitors, inductors, resistors, diodes, conductive lines, or other elements, depending on the circuit design. Integrated circuits incorporate planar field-effect transistors (FETs) in which current flows through a semiconducting channel between a source and a drain, in response to a voltage applied to a control gate.

Since the drive current, and therefore speed, of a transistor is proportional to the gate width of the transistor, faster transistors generally require larger gate width. Thus, there is a trade-off between transistor size and speed, and “fin” field-effect transistors (FinFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. However, FinFETs have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, the FinFET structure, and a gate-all-around (GAA) structure. The GAA device structure includes several lattice matched channels suspended in a stacked configuration and connected by source/drain regions. The GAA structure provides good electrostatic control and can find broad adoption in complementary metal oxide semiconductor (CMOS) wafer manufacturing.

One example of GAA technology is complementary field-effect transistor (CFET), where “negative metal-oxide-semiconductor (NMOS) FETs” and “positive metal-oxide-semiconductor (PMOS) FETs” are vertically stacked on top of each other. CFETs have increased on-chip device density and reduced area consumption compared to GAA transistors. When stacking NMOS FETs and PMOS FETs in a monolithic manner, the n and p superlattice (e.g., the NMOS FET or PMOS FET, respectively) are deposited sequentially with a middle sacrificial layer that is selectively removed and replaced with a middle dielectric isolation (MDI) layer during processing. The MDI layer serves to electrically isolate the lower-level GAA from the upper-level GAA.

Each n or p superlattice of a CFET includes alternating layers of channel layers and release layers. The channel layers typically comprise silicon (Si). The release layers typically comprise silicon germanium (SiGe) with a low concentration of germanium (Ge). For etch contrast between the middle sacrificial layer verses the channel layers and the release layers, the middle sacrificial layer comprises SiGe with a high concentration of Ge.

Shrinking of the materials currently used as NMOS FETs and PMOS FETs have become a challenge due to changes in basic properties, such as threshold voltage (Vₜ). The Vₜ tuning range will be limited by the film thickness variation with further scaling down of device sizes.

There are also challenges associated with conventional dipole engineering techniques. To achieve the desired dipole effect, the desired element is driven from a deposited film with spike anneal and removed after drive in. The spike anneal can potentially cause an equivalent oxide thickness (EOT) penalty and high thermal budget because free oxygen atoms in the gate dielectric layers and the overlaying dipole stack diffuse downward to oxidize the underlying silicon layer.

Additionally, precise control of the amount of dipole species is crucial to achieve desired threshold voltage Vₜ (or multiple threshold voltages (multi-Vₜ)) for transistors. Conventional dipole engineering techniques include “dipole first” processes and “dipole last” processes. Typically, dipole first processes include flowing a metal-containing precursor and a reactant over an interfacial layer to deposit metal atoms on the interfacial layer (forming a treated interfacial layer) to achieve desired dipole effect, followed by depositing a high-κ dielectric layer on the treated interfacial layer. Conventional dipole first processes also include repairing the interfacial layer after treatment.

Dipole last processes typically include forming an interfacial layer on a substrate, forming a high-κ dielectric layer on the interfacial layer, flowing a metal-containing precursor and a reactant over the high-κ dielectric layer to deposit metal atoms on the high-κ dielectric layer, and annealing the substrate to drive the metal atoms into an interface of the interfacial layer and the high-κ dielectric layer to achieve desired dipole effect. In dipole last processes, instead of forming an ultrathin surface adsorption layer, an atomic layer deposition (ALD) process is performed to deposit a dipole layer having a thickness in a range of from 3 Å to 20 Å that contains the metal atoms, usually in their oxide or nitride form. A capping material is typically needed on top of the dipole oxide/nitride layer to avoid silicon oxide regrowth during the annealing process. Conventional dipole last processes also include repairing the high-κ dielectric layer after the annealing process.

In conventional dipole last processes, multiple annealing steps would be required to reach an increased Vₜ, such as the Vₜ achieved by a conventional dipole first process. Also, particularly in dipole first processes, there are challenges associated with Vₜ shift and leakage. Tuning Vₜ is even more challenging in CFETs compared to GAA transistors due to the CFETs' increased on-chip device density and reduced area consumption.

Accordingly, there is a need for improved methods of manufacturing CFETs that meet reduced thickness, reduced leakage, lower thermal budget, and Vₜ requirements (including multi-Vₜ), and have minimal, if any, EOT penalty.

### SUMMARY

One or more embodiments of the disclosure are directed to a method of forming a complementary field-effect transistor (CFET). The method comprises depositing an interfacial layer on a vertically stacked superlattice structure on a substrate, the substrate including a first portion, a second portion, and a third portion. The vertically stacked superlattice structure comprises a first horizontal gate-all-around (hGAA) structure on a top surface of the substrate, a middle dielectric isolation layer on a top surface of the first hGAA structure, and a second hGAA structure on a top surface of the middle dielectric isolation layer. The interfacial layer forms on the first hGAA structure, the middle dielectric isolation layer, and the second hGAA structure. Next, the method comprises depositing a high-κ dielectric layer on the interfacial layer, depositing a first p-type dipole layer on the high-κ dielectric layer, depositing a first p-type capping layer on the first p-type dipole layer, depositing a first protective layer on the first portion of the substrate, and etching the vertically stacked superlattice structure to remove the first protective layer, and a portion of the first p-type capping layer and a portion of the first p-type dipole layer from the second portion of the substrate. The first portion has a first threshold voltage (Vₜ) and the second portion has a second Vₜ. After etching the vertically stacked superlattice structure to remove the first protective layer, and a portion of the first p-type capping layer and a portion of the first p-type dipole layer from the second portion of the substrate, the method comprises depositing a second p-type dipole layer on the first portion, the second portion, and the third portion of the substrate, the second p-type dipole layer forming on the first hGAA structure, the middle dielectric isolation layer, and the second hGAA structure, depositing a second p-type capping layer on the second p-type dipole layer, the second p-type capping layer filling trenches in the vertically stacked superlattice structure, etching the vertically stacked superlattice structure to remove a portion of the first p-type capping layer, a portion of the first p-type dipole layer, a portion of the second p-type capping layer, and a portion of the second p-type dipole layer to expose the high-κ dielectric layer on the second hGAA structure, depositing a first n-type dipole layer on the exposed high-κ dielectric layer on the second hGAA structure, depositing a first n-type capping layer on the first n-type dipole layer, depositing a second protective layer on the first portion of the substrate, etching the vertically stacked superlattice structure to remove the second protective layer to expose the first portion of the first n-type capping layer, and remove a portion of the first n-type capping layer and a portion of the first n-type dipole layer from the second portion and third portion of the substrate, depositing a second n-type dipole layer on the first portion, the second portion, and the third portion of the substrate, the second n-type dipole layer forming on the second hGAA structure, depositing a second n-type capping layer on the second n-type dipole layer, the second n-type capping layer filling the trenches in the vertically stacked superlattice structure, etching the vertically stacked superlattice structure to remove a portion of the second n-type capping layer and a portion of the second n-type dipole layer from the first portion, the second portion, and the third portion of the substrate, depositing a third protective layer on the first portion and the second portion of the substrate, etching the vertically stacked superlattice structure to remove the third protective layer, and a portion of the first n-type capping layer and a portion of the first n-type dipole layer from the second portion of the substrate, and to expose the high-κ dielectric layer on each of the first hGAA structure and the second hGAA structure, annealing the substrate at a temperature of less than or equal to 1000° C. to drive atoms from each of the first p-type dipole layer, the second p-type dipole layer, the first n-type dipole layer, and the second n-type dipole layer into the high-dielectric layer to form an annealed high-κ dielectric layer, and etching the vertically stacked superlattice structure to remove each of the first p-type dipole layer, the first p-type capping layer, the second p-type dipole layer, the second p-type capping layer, the first n-type dipole layer, the first n-type capping layer, the second n-type dipole layer, and the second p-type capping layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1A illustrates a process flow diagram of a method of manufacturing a complementary field-effect transistor (CFET) according to one or more embodiments;

FIG. 1B illustrates a schematic cross-sectional view of a vertically stacked superlattice structure on a substrate having a first portion, a second portion, and a third portion according to one or more embodiments;

FIG. 2A illustrates a bi-cross-sectional view of a vertically stacked superlattice structure on a substrate showing a first cross-section view through gates (across fins) and a second cross-section view through fins (across gate) according to one or more embodiments;

FIG. 2B illustrates a bi-cross-sectional view of the substrate of FIG. 2A after deposition of an interfacial layer on the vertically stacked superlattice structure and deposition of a high-κ dielectric layer on the interfacial layer according to one or more embodiments;

FIG. 2C illustrates a bi-cross-sectional view of the substrate of FIG. 2B after deposition of a first p-type dipole layer on the high-κ dielectric layer according to one or more embodiments;

FIG. 2D illustrates a bi-cross-sectional view of the substrate of FIG. 2O after deposition of a first p-type capping layer on the first p-type dipole layer according to one or more embodiments;

FIG. 2E illustrates a bi-cross-sectional view of the substrate of FIG. 2D after deposition of a first protective layer on the first portion of the substrate according to one or more embodiments;

FIG. 2F illustrates a bi-cross-sectional view of the substrate of FIG. 2E after etching the vertically stacked superlattice structure to remove the first protective layer from the first portion of the substrate according to one or more embodiments;

FIG. 2G illustrates a bi-cross-sectional view of the substrate of FIG. 2F after deposition of a second p-type dipole layer on the first portion, the second portion, and the third portion of the substrate according to one or more embodiments;

FIG. 2H illustrates a bi-cross-sectional view of the substrate of FIG. 2G after deposition of a second p-type capping layer on the second p-type dipole layer, the second p-type capping layer filling the trenches in the vertically stacked superlattice structure according to one or more embodiments;

FIG. 2I illustrates a bi-cross-sectional view of the substrate of FIG. 2H after etching the vertically stacked superlattice structure to remove a portion of the first p-type capping layer, a portion of the first p-type dipole layer, a portion of the second p-type capping layer, and a portion of the second p-type dipole layer to expose high-κ dielectric layer according to one or more embodiments;

FIG. 2J illustrates a bi-cross-sectional view of the semiconductor substrate of FIG. 2I after deposition of a first n-type dipole layer on the exposed high-κ dielectric layer according to one or more embodiments;

FIG. 2K illustrates a bi-cross-sectional view of the semiconductor substrate of FIG. 2J after deposition of a first n-type capping layer on the first n-type dipole layer according to one or more embodiments;

FIG. 2L illustrates a bi-cross-sectional view of the semiconductor substrate of FIG. 2K after deposition of a second protective layer on the first portion of the substrate according to one or more embodiments;

FIG. 2M illustrates a bi-cross-sectional view of the semiconductor substrate of FIG. 2L after etching the vertically stacked superlattice structure to remove the second protective layer to expose the first portion of the first n-type capping layer, and remove a portion of the first n-type capping layer and a portion of the first n-type dipole layer from the second portion and third portion of the substrate according to one or more embodiments;

FIG. 2N illustrates a bi-cross-sectional view of the semiconductor substrate of FIG. 2M after deposition of a second n-type dipole layer on the first portion, the second portion, and the third portion of the substrate according to one or more embodiments;

FIG. 2O illustrates a bi-cross-sectional view of the semiconductor substrate of FIG. 2N after deposition of a second n-type capping layer on the second n-type dipole layer, the second n-type capping layer filling the trenches in the vertically stacked superlattice structure according to one or more embodiments;

FIG. 2P illustrates a bi-cross-sectional view of the semiconductor substrate of FIG. 2O after etching the vertically stacked superlattice structure to remove a portion of the second n-type capping layer and a portion of the second n-type dipole layer from the first portion, the second portion, and the third portion of the substrate according to one or more embodiments;

FIG. 2Q illustrates a bi-cross-sectional view of the semiconductor substrate of FIG. 2P after depositing a third protective layer on the first portion and the second portion of the substrate according to one or more embodiments;

FIG. 2R illustrates a bi-cross-sectional view of the semiconductor substrate of FIG. 2Q after etching the vertically stacked superlattice structure to remove the third protective layer, and a portion of the first n-type capping layer and a portion of the first n-type dipole layer from the second portion of the substrate, and to expose the high-κ dielectric layer according to one or more embodiments;

FIG. 2S illustrates a bi-cross-sectional view of the semiconductor substrate of FIG. 2R after annealing the substrate at a temperature of less than or equal to 1000° C. to drive atoms from each of the first p-type dipole layer, the second p-type dipole layer, the first n-type dipole layer, and the second n-type dipole layer into the high-κ dielectric layer to form an annealed high-κ dielectric layer according to one or more embodiments; and

FIG. 2T illustrates a bi-cross-sectional view of the semiconductor substrate of FIG. 2S after etching the vertically stacked superlattice structure to remove each of the first p-type dipole layer, the first p-type capping layer, the second p-type dipole layer, the second p-type capping layer, the first n-type dipole layer, the first n-type capping layer, the second n-type dipole layer, and the second p-type capping layer according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of +15%, or less, of the numerical value. For example, a value differing by +14%, +10%, +5%, +2%, or +1%, would satisfy the definition of about.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate, such as a semiconductor substrate, and exhibit a doping profile suitable for a particular application. The gate is positioned over the channel region and includes a gate dielectric interposed between a gate electrode and the channel region in the semiconductor substrate.

As used herein, the term “field effect transistor” or “FET” refers to a transistor that uses an electric field to control the electrical behavior of the device. Field effect transistors are voltage controlled devices where their current carrying ability is changed by applying an electric field. Field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated Is and current entering the channel at the drain (D) is designated I_{D}. Drain-to-source voltage is designated V_{DS}. By applying voltage to gate (G), the current entering the channel at the drain (i.e., I_{D}) can be controlled.

The metal-oxide-semiconductor field-effect transistor (MOSFET) is a type of field-effect transistor (FET) and is used in integrated circuits and high speed switching applications. MOSFET has an insulated gate, whose voltage determines the conductivity of the device. This ability to change conductivity with the amount of applied voltage is used for amplifying or switching electronic signals. A MOSFET is based on the modulation of charge concentration by a metal-oxide semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or NMOS FET, then the source and drain are n+ regions and the body is a p-type substrate region. If the MOSFET is a p-channel or PMOS FET, then the source and drain are p+ regions and the body is an n-type substrate region. The source is so named because it is the source of the charge carriers (electrons for n-channel, holes for p-channel) that flow through the channel; similarly, the drain is where the charge carriers leave the channel.

A NMOS FET is made up of an n-type source and drain and a p-type substrate. When a voltage is applied to the gate, holes in the body (p-type substrate) are driven away from the gate. This allows forming an n-type channel between the source and the drain and a current is carried by electrons from source to the drain through an induced n-type channel. Logic gates and other digital devices implemented using NMOSs are said to have NMOS logic. There are three modes of operation in a NMOS called the cut-off, triode and saturation. Circuits with NMOS logic gates dissipate static power when the circuit is idling, since DC current flows through the logic gate when the output is low.

A PMOS FET is made up of a p-type source and drain and an n-type substrate. When a positive voltage is applied between the source and the gate (negative voltage between gate and source), a p-type channel is formed between the source and the drain with opposite polarities. A current is carried by holes from source to the drain through an induced p-type channel. A high voltage on the gate will cause a PMOS not to conduct, while a low voltage on the gate will cause it to conduct. Logic gates and other digital devices implemented using PMOS are said to have PMOS logic. PMOS technology is low cost and has a good noise immunity.

In a NMOS, carriers are electrons, while in a PMOS, carriers are holes. When a high voltage is applied to the gate, NMOS will conduct, while PMOS will not. Furthermore, when a low voltage is applied in the gate, NMOS will not conduct and PMOS will conduct. NMOS are considered to be faster than PMOS, since the carriers in NMOS, which are electrons, travel twice as fast as holes, which are the carriers in PMOS. But PMOS devices are more immune to noise than NMOS devices. Furthermore, NMOS integrated circuits would be smaller than PMOS integrated circuits (that give the same functionality), since the NMOS can provide one-half of the impedance provided by a PMOS (which has the same geometry and operating conditions).

As used herein, the term “fin field-effect transistor (FinFET)” refers to a MOSFET transistor built on a substrate where the gate is placed on two, three, or four sides of the channel or wrapped around the channel, forming a double gate structure. FinFET devices have been given the generic name FinFETs because the source/drain region forms “fins” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanowires or nanoslabs or nanosheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “complementary field-effect transistor (CFET)” refers to a transistor that includes NMOS FET devices and PMOS FET devices stacked on each other. Each of the NMOS FET devices and the PMOS FET devices that form the CFET are GAA transistors or hGAA transistors.

As used herein, the term “nanowire” refers to a nanostructure, with a diameter on the order of a nanometer (10-9 meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm, or from 0.5 nm to 500 nm, or from 0.5 nm to 100 nm, or from 1 nm to 500 nm, or from 1 nm to 100 nm, or from 1 nm to 50 nm.

Without intending to be bound by theory, it is thought that relaxation in a vertically stacked superlattice structure comprising one or more hGAAs causes defects in nanosheet channel layers within the structure. Embodiments of the present disclosure advantageously provide transistors which comprise a fully strained vertically stacked superlattice structure having nanosheet channel layers that are free or substantially free of defects. In some embodiments, the presence of defects in the nanosheet channel layers are determined by a reciprocal space mapping (RSM) method. Without intending to be bound by theory, a RSM method is an x-ray diffraction method of collecting diffraction data of the vertically stacked superlattice structure in which the presence of defects may be observed. As used herein, the term “substantially free” means that the nanosheet channel layers are substantially free of defects as determined by an RSM method.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

Embodiments of the disclosure generally relate to the field of electronic device manufacturing, and in particular, to transistors. More particularly, embodiments of the disclosure are directed to CFETs and methods of manufacturing CFETs. The devices and processes are described using this context, though the skilled artisan will recognize that the disclosed devices and processes are not limited to the illustrated applications.

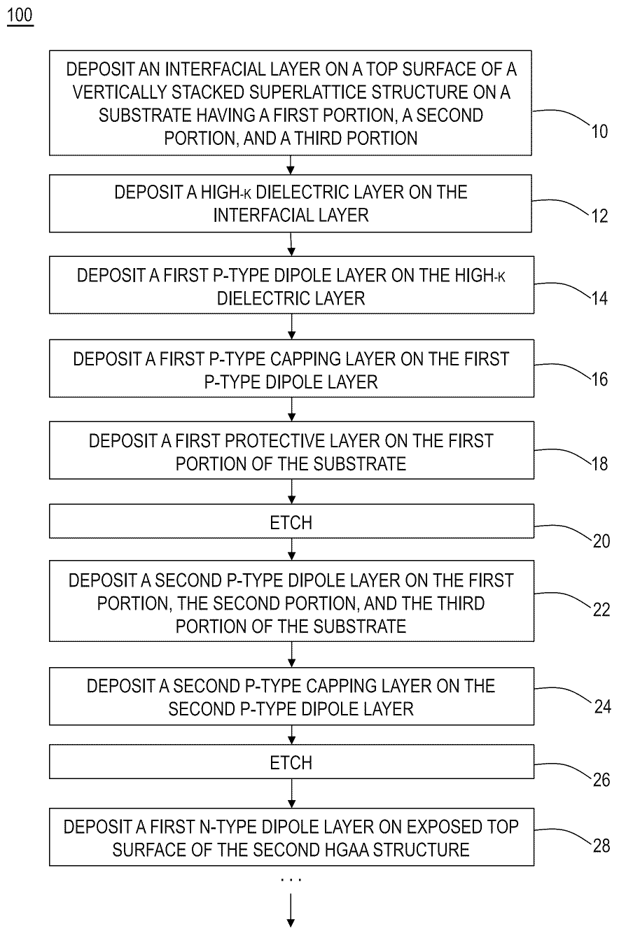

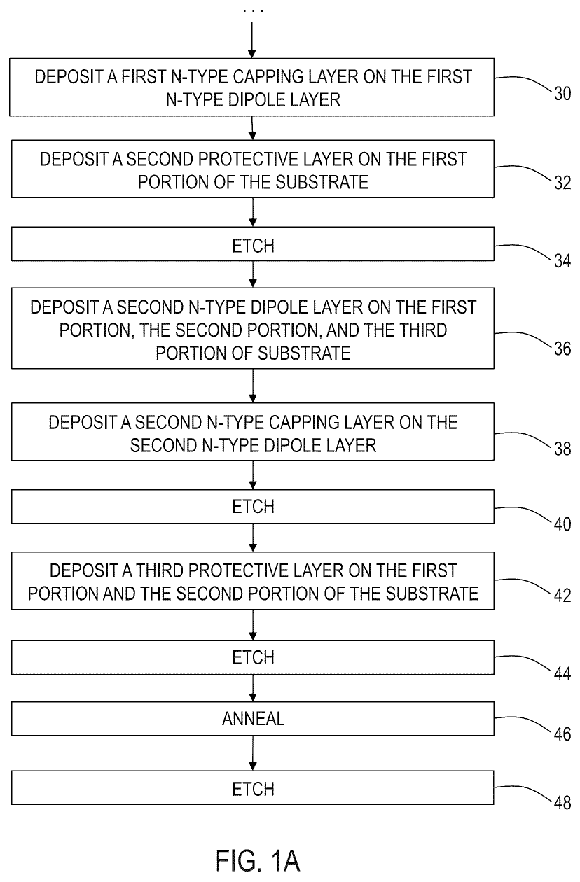

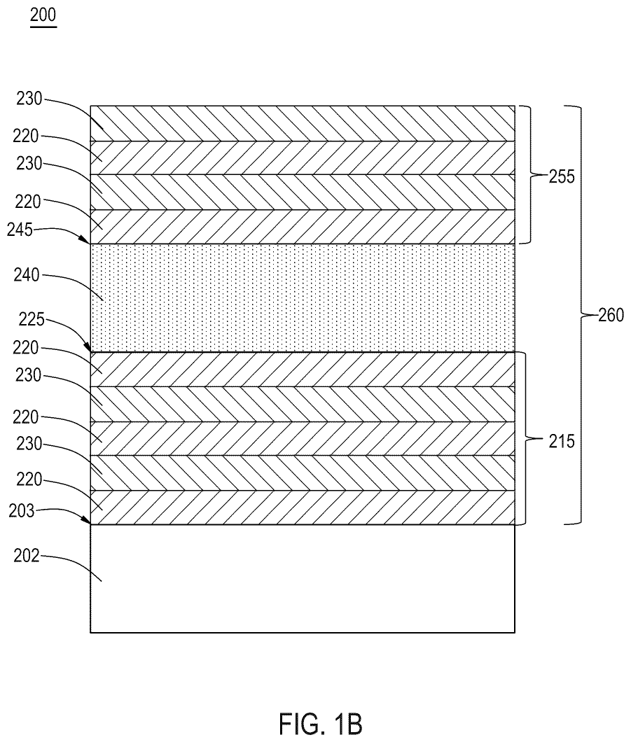

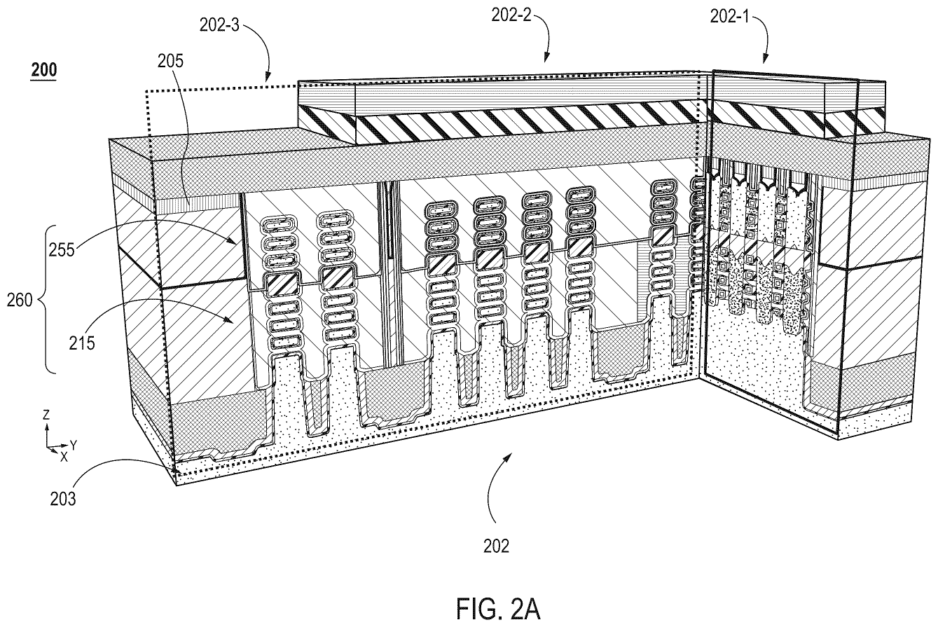

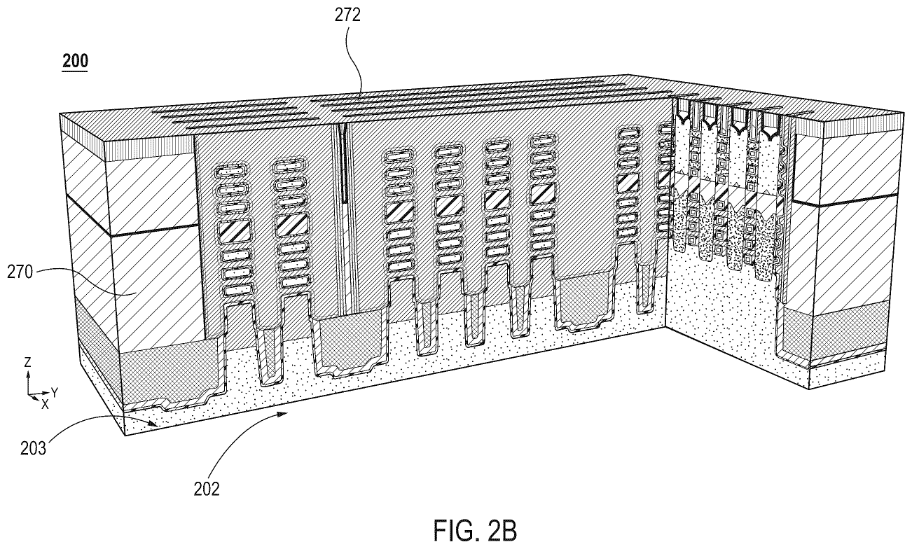

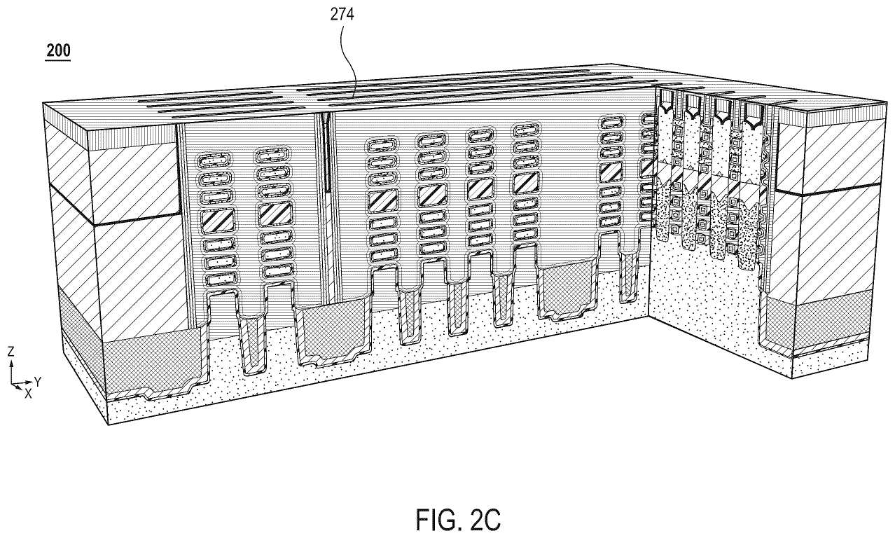

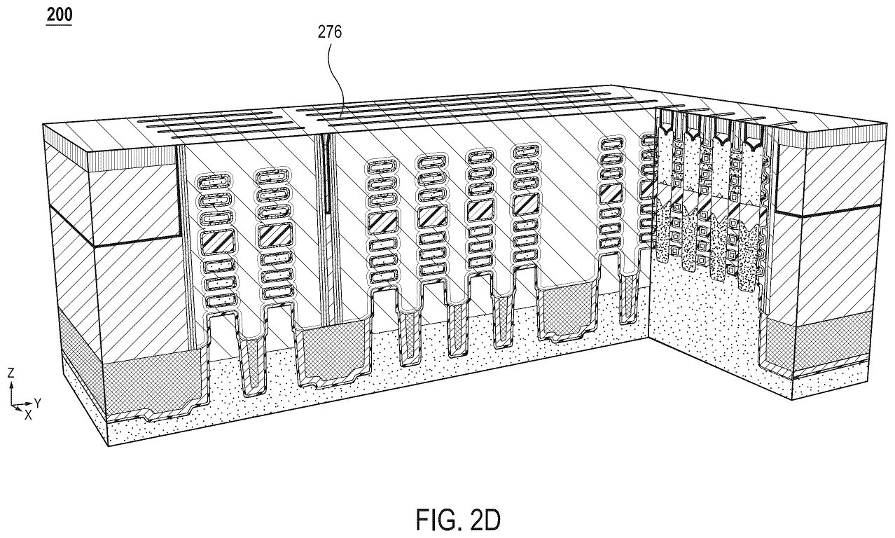

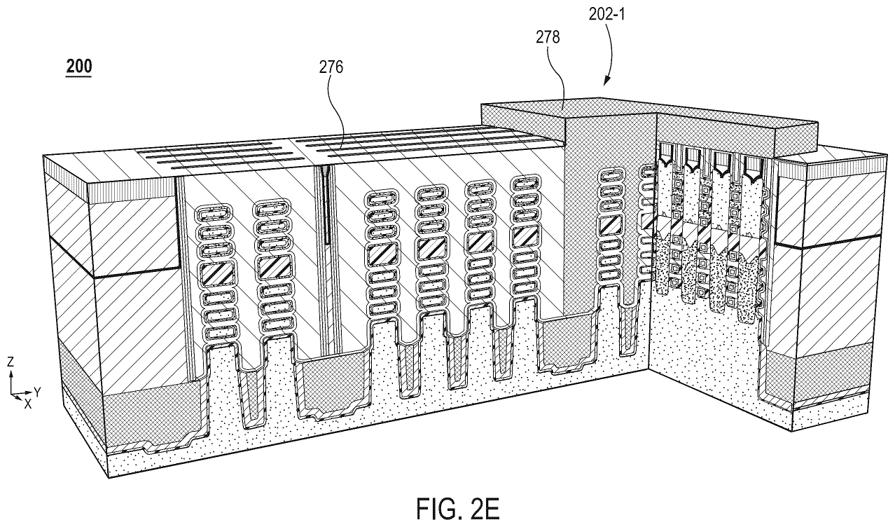

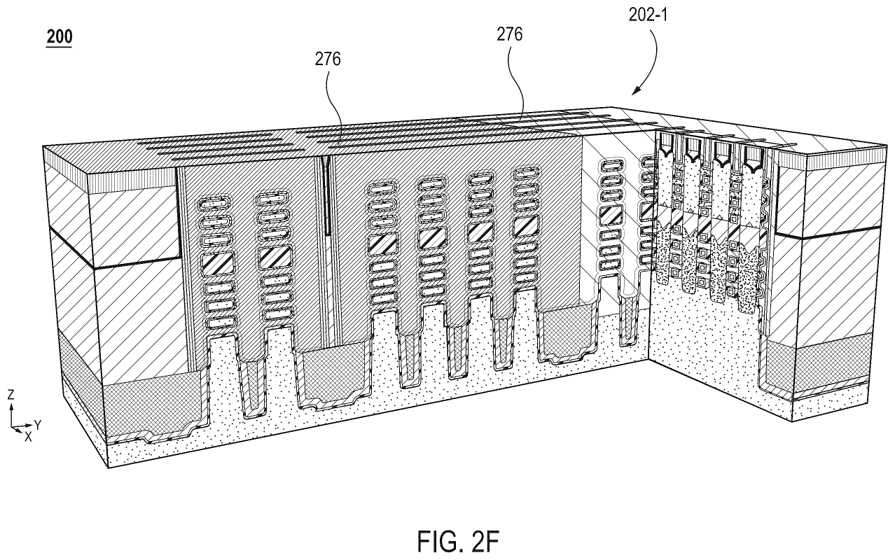

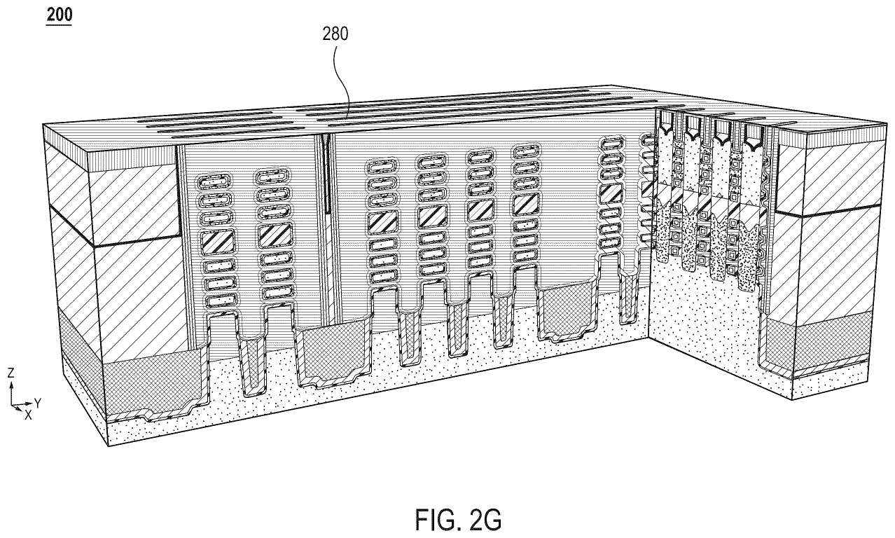

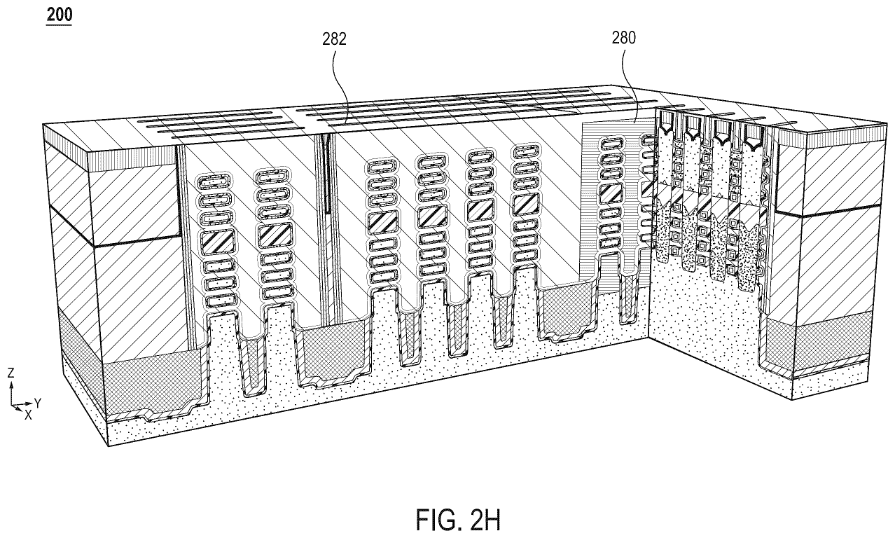

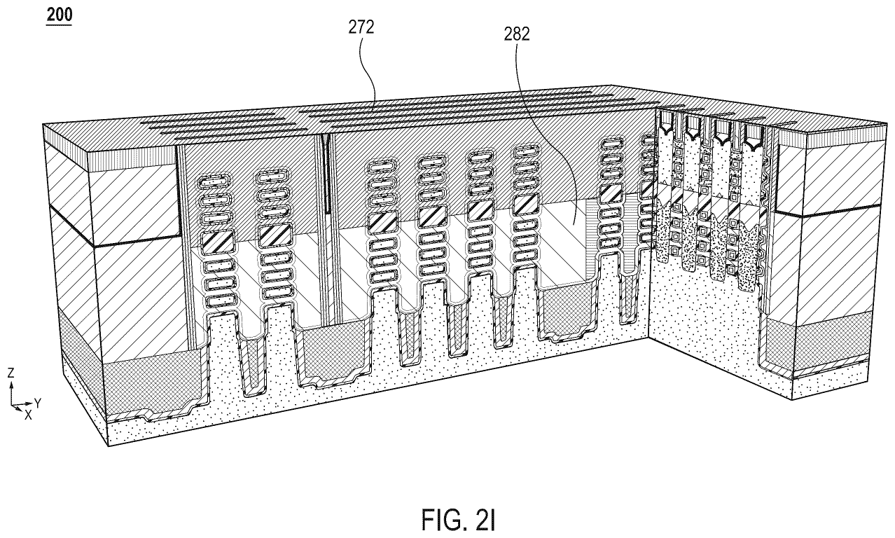

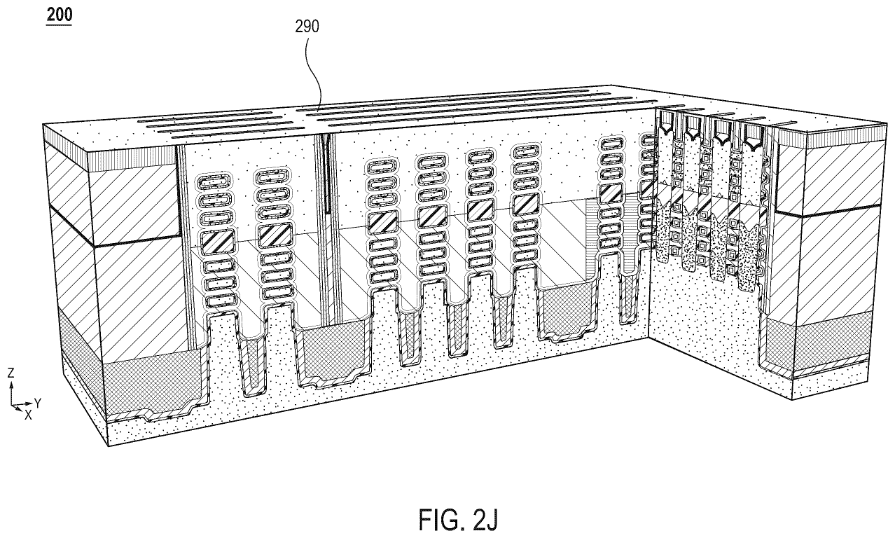

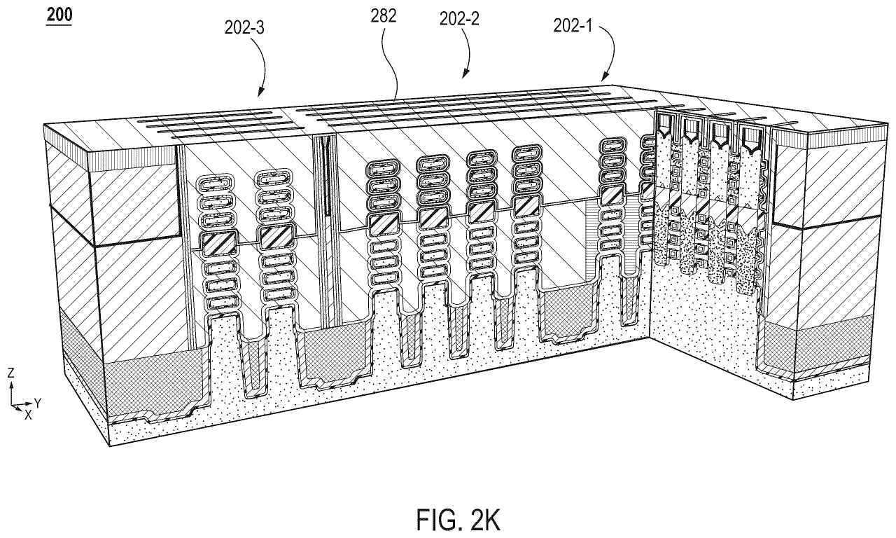

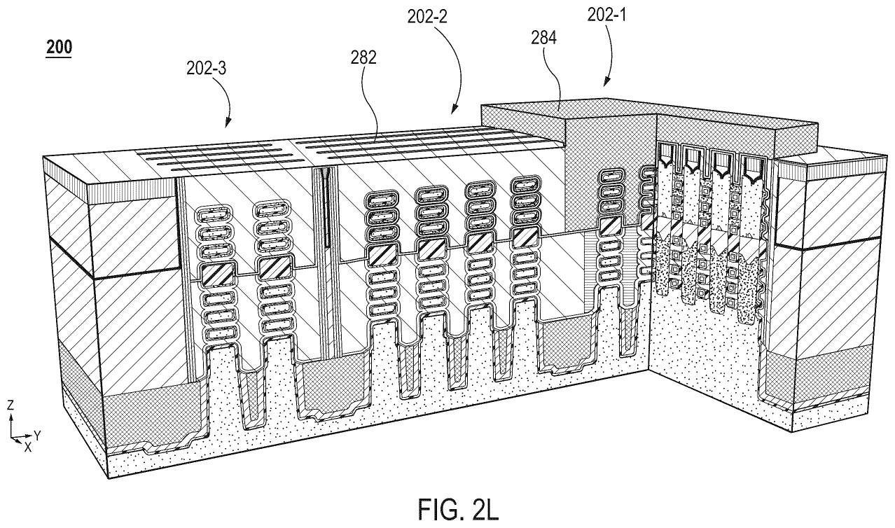

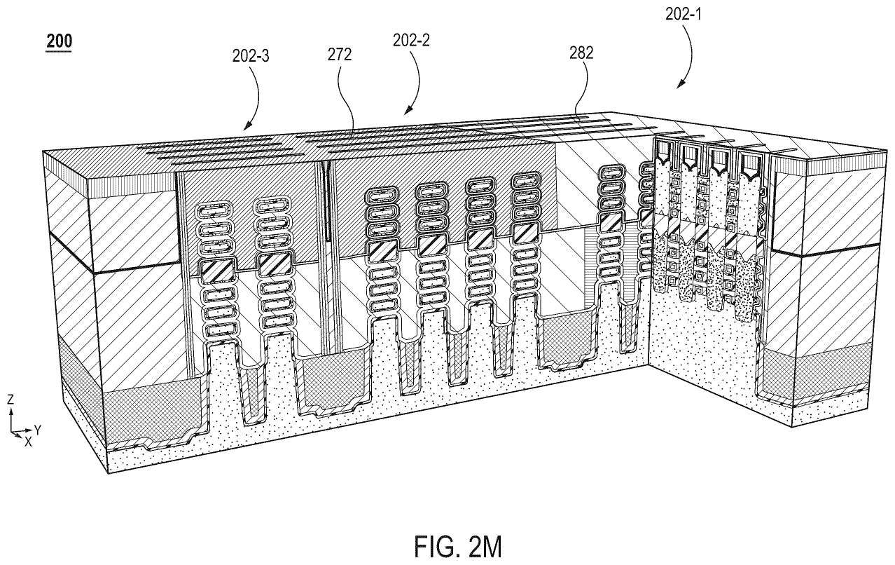

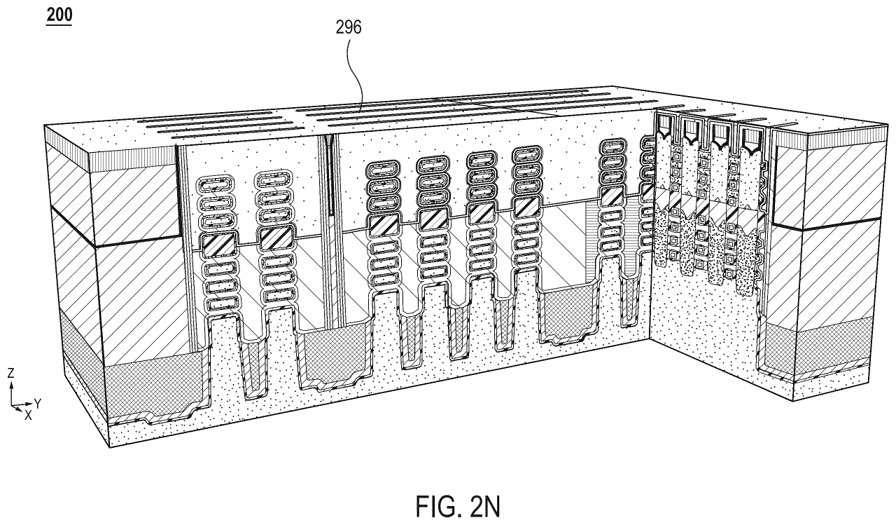

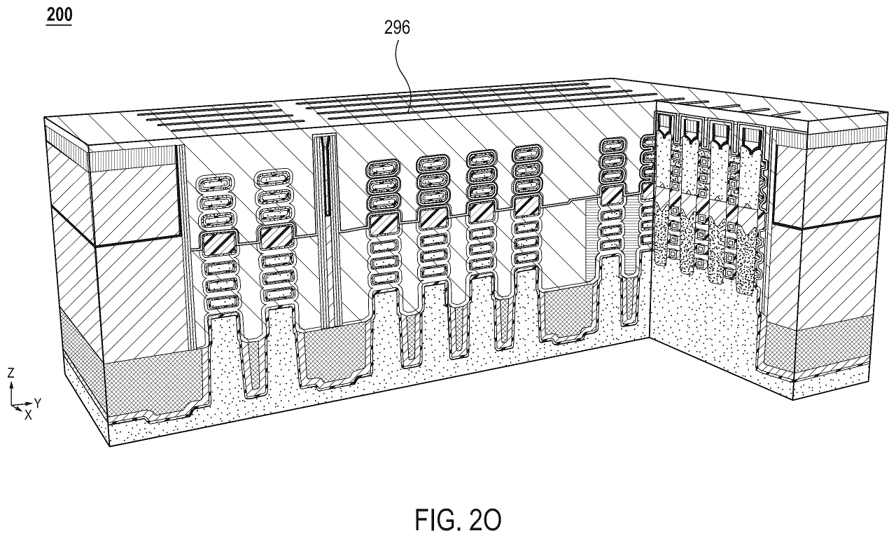

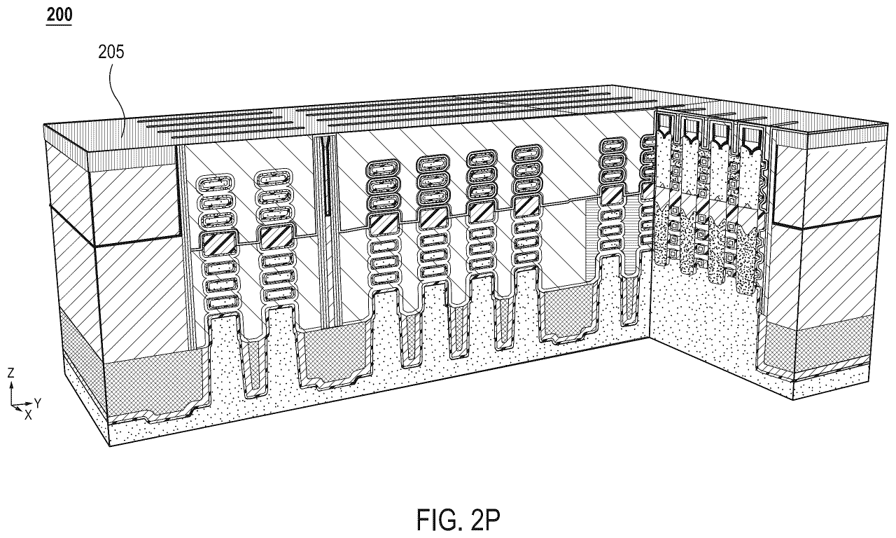

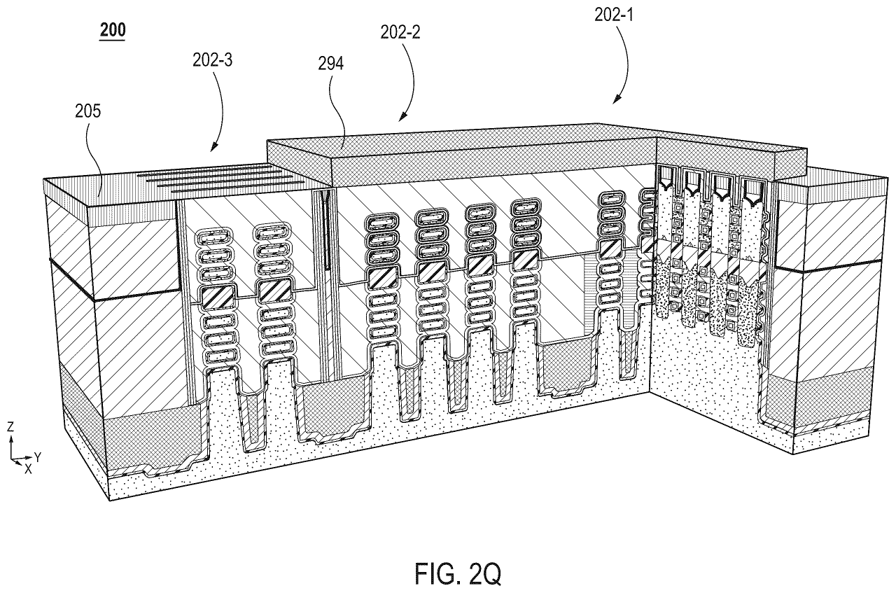

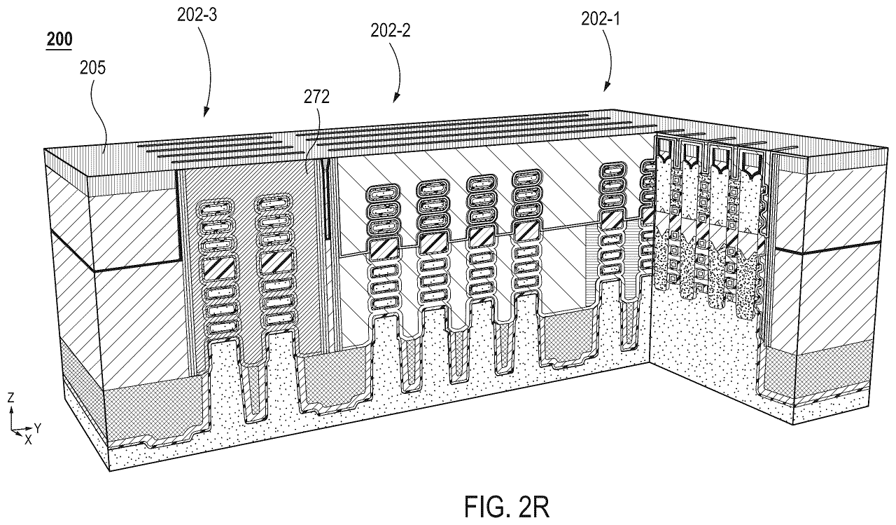

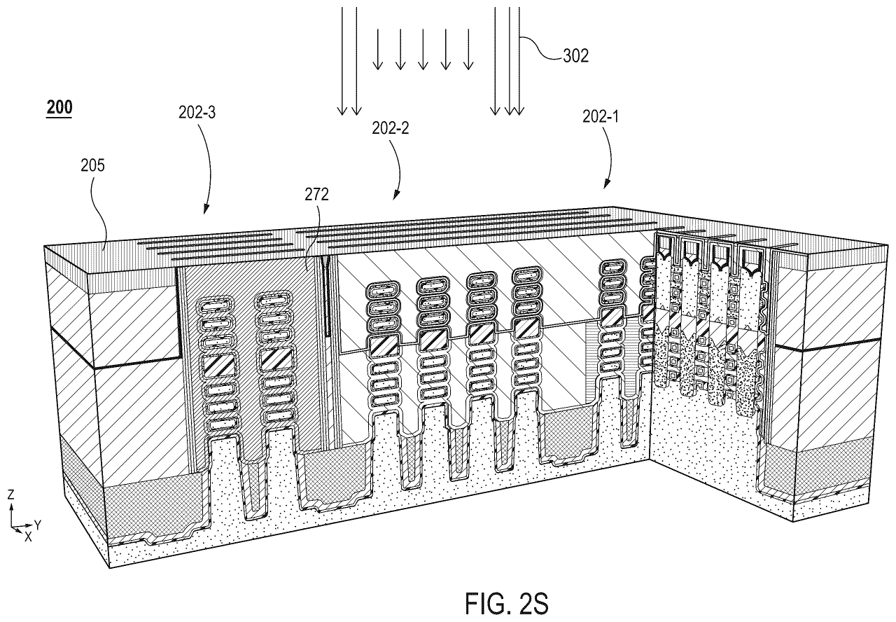

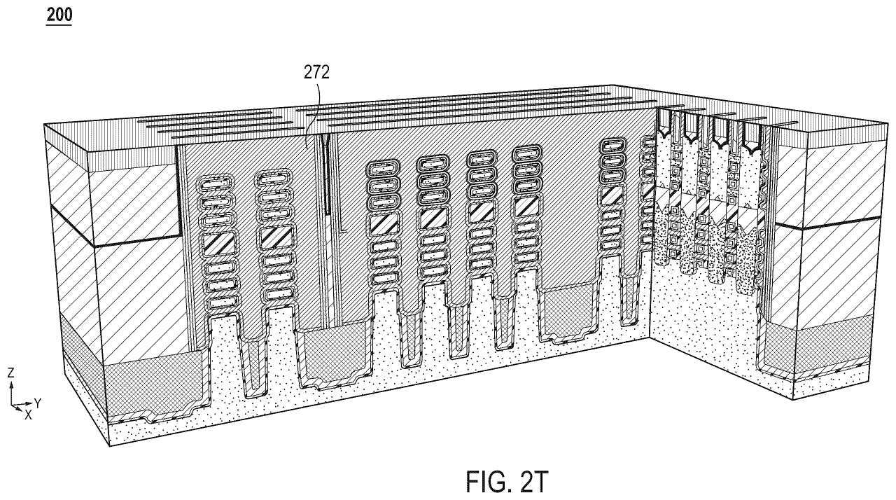

FIG. 1A illustrates a process flow diagram of a method 100 of manufacturing a CFET. FIGS. 2A-2T illustrate bi-cross-sectional views of an electronic device (e.g., a transistor such as CFET 200) according to one or more embodiments. The CFET 200 shown in FIGS. 2A-2T may be manufactured by the method 100 illustrated in FIG. 1A.

FIG. 1B illustrates a schematic cross-sectional view of the CFET 200 having a vertically stacked superlattice structure 260 on a substrate 202. The substrate 202 has a top surface 203. The substrate 202 can be any suitable substrate material. In one or more embodiments, the substrate 202 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), other semiconductor materials, or any combination thereof. In one or more embodiments, the substrate 202 comprises one or more of silicon (Si), germanium (Ge), gallium (Ga), arsenic (As), indium (In), phosphorus (P), or selenium (Se). Although a few examples of materials from which the substrate 202 may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In one or more embodiments, the substrate 202 is a p-type or n-type substrate. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

In one or more embodiments, the vertically stacked superlattice structure 260 comprises one or more horizontal gate-all-around (hGAA) structures 215, 255 on the substrate 202. In some embodiments, the vertically stacked superlattice structure 260 comprises a first or lower horizontal gate-all-around (hGAA) structure 215 on the substrate 202. In some embodiments, the vertically stacked superlattice structure 260 comprises a first or lower horizontal gate-all-around (hGAA) structure 215 on the top surface 203 of the substrate 202. In some embodiments, the vertically stacked superlattice structure comprises a second or upper horizontal gate-all-around (hGAA) structure 255. Without intending to be bound by any particular theory of operation, the first or lower hGAA 215 and the second or upper hGAA 255 may independently comprise the same structure having the same layers. In one or more illustrated embodiments, the vertically stacked superlattice structure 260 comprises the first hGAA structure 215 on the top surface 203 of the substrate 202, a middle dielectric isolation (MDI) layer 240 on a top surface 225 of the first hGAA structure 215, and the second hGAA structure 255 on a top surface 245 of the MDI layer 240.

In some embodiments, each of the first hGAA 215 and the second hGAA 255 comprise alternating layers of nanosheet channel layer 230 and nanosheet release layer 220. In some embodiments, the plurality of nanosheet release layers 220 and the plurality of nanosheet channel layers 230 can comprise any number of lattice matched material pairs suitable for forming the vertically stacked superlattice structure 260. In some embodiments, each of the first hGAA 215 and the second hGAA 255 have in a range of from 1 to 5 pairs of alternating layers of nanosheet channel layers 230 and nanosheet release layers 220.

The nanosheet release layers 220 may have any suitable thickness. In one or more embodiments, each nanosheet release layer 220 has a thickness in a range of from 5 nm to 15 nm. The nanosheet channel layers 230 may have any suitable thickness. In one or more embodiments, each nanosheet channel layer 230 has a thickness in a range of from 5 nm to 15 nm.

In some embodiments, each of the nanosheet channel layers 230 independently comprises silicon (Si). In some embodiments, each of the nanosheet release layers 220 independently comprises silicon germanium (SiGe).

In one or more embodiments, a sacrificial layer (not shown) is formed between the first or lower hGAA 215 and the second or upper hGAA 255. In one or more embodiments, the sacrificial layer is selectively removed and replaced with a middle dielectric isolation (MDI) layer 240 during processing. The MDI layer 240 serves to electrically isolate the source/drain regions of the first or lower GAA 215 from the source/drain regions of the second or upper GAA 255. The MDI layer 240 may comprise any suitable material. In one or more embodiments, the MDI layer 240 comprises silicon germanium (SiGe). In one or more embodiments, the MDI layer 240 comprises silicon germanium (SiGe) having a higher concentration of germanium (Ge) than the SiGe of the nanosheet release layers 220.

In one or more embodiments, the MDI layer 240 may have any suitable thickness. In some embodiments, the MDI layer 240 has a thickness in a range of from 15 nm to 90 nm, including a range of from 15 nm to 80, a range of from 20 nm to 75 nm, a range of from 15 nm to 60 nm, a range of from 15 nm to 50 nm, a range of from 15 nm to 75 nm, and a range of from 20 nm to 50 nm. In some embodiments, increasing the thickness of the MDI layer 240 to greater than 40 nm increases the etch selectivity between the MDI layer 240 and the nanosheet release layer 220.

As recognized by one of skill in the art, during subsequent processing, the sacrificial layer may be removed and replaced with the MDI layer 240. In one or more embodiments, the sacrificial layer (not shown) is selectively removed. Selectively removing the sacrificial layer may be performed by any suitable means known to the skilled artisan. In some embodiments, selectively removing the sacrificial layer comprises an etch process that removes the sacrificial layer and does not remove the nanosheet release layers 220. In some embodiments, the etch process comprises one or more of a wet etch process or a dry etch process. In some embodiments, the etch process is a directional etch.

In one or more unillustrated embodiments, the vertically stacked superlattice structure 260 includes a plurality of vertically extending trenches and a plurality of horizontally extending trenches. In one or more embodiments, the plurality of vertically extending trenches extend vertically from a top surface of the second or upper hGAA 255, through the MDI layer 240, and through the first or lower hGAA 215 to the top surface 203 of the substrate 202. In one or more embodiments, the plurality of horizontally extending trenches extend horizontally through the plurality of nanosheets in the second or upper hGAA 255, and through the plurality of nanosheets in the first or lower hGAA 215.

Embodiments of the present disclosure advantageously provide methods of manufacturing electronic devices (e.g., CFETs) that meet reduced thickness, reduced leakage, lower thermal budget, and Vₜ requirements (including multi-Vₜ), and have improved device performance and reliability. Embodiments of the present disclosure advantageously provide improved integration schemes that allow for increased Vₜ and improved multi-Vₜ tuning ability. Embodiments of the disclosure improve Vₜ significantly without EOT penalty.

Embodiments of the present disclosure advantageously provide integration schemes that reduce the number of lithography patterning steps. Some embodiments advantageously provide integration schemes that eliminate the requirement for deposition of a liner on top of the CFET (e.g., on top of one or more of an NMOS FET or PMOS FET), reduce the number of etching steps and eliminate the requirement of a carbon fill step. It has been found that reducing the number of etching steps using the processes described herein advantageously eliminates Vₜ variation in the CFET. Embodiments of the present disclosure advantageously provide improved processes that reduce the number of annealing steps to drive-in metal atoms from the p-type dipole layers and the n-type dipole layers.

Embodiments of the present disclosure advantageously provide improved integration schemes that include conventional dipole engineering techniques such as dipole first processes and/or dipole last processes. Advantageously, the integration schemes described herein allow can include conventional dipole engineering techniques without the need for repairing the interfacial layer after treatment (in dipole first processes) or repairing the high-κ dielectric layer after the annealing process (in dipole last processes).

FIG. 1A illustrates a process flow diagram of a method 100 of manufacturing a complementary field-effect transistor (CFET). The method 100 comprises, at operation 10, depositing an interfacial layer on a top surface of a vertically stacked superlattice structure on a substrate. At operation 12, the method 100 includes depositing a high-κ dielectric layer on the interfacial layer. At operation 14, the method 100 includes depositing a first p-type dipole layer on the high-κ dielectric layer. At operation 16, the method 100 includes depositing a first p-type capping layer on the first p-type dipole layer. At operation 18, the method includes depositing a first protective layer on a first portion of the substrate. At operation 20, the method 100 includes etching the vertically stacked superlattice structure to remove the first protective layer, and a portion of the first p-type capping layer and a portion of the first p-type dipole layer from the second portion of the substrate. At operation 22, the method 100 includes depositing a second p-type dipole layer on the first portion, the second portion, and the third portion of the substrate. At operation 24, the method 100 includes depositing a second p-type capping layer on the second p-type dipole layer. At operation 26, the method 100 includes etching the vertically stacked superlattice structure to remove a portion of the first p-type capping layer, a portion of the first p-type dipole layer, a portion of the second p-type capping layer, and a portion of the second p-type dipole layer to expose the high-κ dielectric layer on the second hGAA structure. At operation 28, the method 100 includes depositing a first n-type dipole layer on the exposed high-κ dielectric layer on the second hGAA structure. At operation 30, the method 100 includes depositing a first n-type capping layer on the first n-type dipole layer. At operation 32, the method 100 includes depositing a second protective layer on the first portion of the substrate. At operation 34, the method 100 includes etching the vertically stacked superlattice structure to remove the second protective layer to expose the first portion of the first n-type capping layer, and remove a portion of the first n-type capping layer and a portion of the first n-type dipole layer from the second portion and third portion of the substrate. At operation 36, the method 100 includes depositing a second n-type dipole layer on the first portion, the second portion, and the third portion of the substrate. At operation 38, the method 100 includes depositing a second n-type capping layer on the second n-type dipole layer. At operation 40, the method 100 includes etching the vertically stacked superlattice structure to remove a portion of the second n-type capping layer and a portion of the second n-type dipole layer from the first portion, the second portion, and the third portion of the substrate. At operation 42, the method 100 includes depositing a third protective layer on the first portion and the second portion of the substrate. At operation 44, the method 100 includes etching the vertically stacked superlattice structure to remove the third protective layer, and a portion of the first n-type capping layer and a portion of the first n-type dipole layer from the second portion of the substrate, and to expose the high-κ dielectric layer on each of the first hGAA structure and the second hGAA structure. At operation 46, the method 100 includes annealing the substrate at a temperature of less than or equal to 1000° C. to drive atoms from each of the first p-type dipole layer, the second p-type dipole layer, the first n-type dipole layer, and the second n-type dipole layer into the high-κ dielectric layer to form an annealed high-κ dielectric layer. At operation 48, the method 100 includes etching the vertically stacked superlattice structure to remove each of the first p-type dipole layer, the first p-type capping layer, the second p-type dipole layer, the second p-type capping layer, the first n-type dipole layer, the first n-type capping layer, the second n-type dipole layer, and the second p-type capping layer.

In one or more embodiments, the method 100 consists essentially of operations 10, 12, 14, 16, 18, 20, 22, 24, 26, 28, 30, 32, 34, 36, 38, 40, 42, 44, 46, and 48. In one or more embodiments, the method 100 consists of operations 10, 12, 14, 16, 18, 20, 22, 24, 26, 28, 30, 32, 34, 36, 38, 40, 42, 44, 46, and 48.

For example, if the work-function was shifted in either P-dipole or N-dipole bandedge after dipole engineering, the methods herein can be used to shift the bandedge the opposite way. For example, methods described herein can shift the bandedge from ultra-low Vₜ (ULVₜ), which is the most P-dipole and/or N-dipole bandedge, respectively, to low Vₜ (LVₜ) or standard Vₜ (SVₜ), or the mid-gap: high Vₜ (HVₜ).

Without intending to be bound by theory, it is thought that selectively etching the dipole layer(s) (e.g., the first p-type dipole layer, the second p-type dipole layer, the first n-type dipole layer, and/or the second n-type dipole layer) and increasing a thickness of one or more of the dipole layer(s) forms a CFET with multiple threshold voltages (multi-Vₜ). Stated differently, when one dipole layer has a first thickness (e.g., a first p-type dipole layer) and another dipole layer has a second thickness (e.g., a second p-type dipole layer), and the first thickness and the second thickness are different, multiple threshold voltages (multi-Vₜ) are formed.

FIGS. 2A-2T illustrate bi-cross-sectional views of an electronic device (e.g., a transistor such as complementary field-effect transistor (CFET) 200) according to one or more embodiments. In particular, FIGS. 2A-2T illustrate a first cross-sectional view through the gates across the fins and a second cross-sectional view through the fins (across the gates). The substrate 202 includes a first portion 202-1, a second portion 202-2, and a third portion 202-3.

The CFET 200 shown in FIGS. 2A-2T may be manufactured by the method 100 illustrated in FIG. 1A.

Referring to FIGS. 1A and 2B, in some embodiments, at operation 10, the interfacial layer 270 is deposited on the top surface of the vertically stacked superlattice structure 260 using a deposition technique, such as, but not limited to, ALD, CVD, PVD, MBE, MOCVD, spin-on, or other insulating layer deposition techniques known to the skilled artisan. In some embodiments, at operation 10, the interfacial layer 270 is deposited on the first hGAA structure 215, the MDI layer 240, and the second hGAA structure 255. In one or more embodiments, the interfacial layer 270 comprises silicon oxide (SiOx). In one or more embodiments, the interfacial layer 270 may be formed by etching and an oxide forming on the surface (e.g., the top surface of the vertically stacked superlattice structure 260).

In some embodiments, at operation 10, a wet chemistry technique is performed to form the interfacial layer 270. The wet chemistry technique may be any suitable technique known to the skilled artisan. In some embodiments, the wet chemistry technique includes a pre-clean process. In some embodiments, the pre-clean process includes using a SC-1 solution comprising one or more of ozone, ammonium hydroxide or hydrogen peroxide. In some embodiments, the pre-clean process includes using a SC-1 solution without ozone, ammonium hydroxide or hydrogen peroxide. In some embodiments, after using the SC-1 solution, the pre-clean process includes using dilute hydrofluoric acid (dilute HF), including greater than 100:1, such as 130:1 dilute HF, to etch away native oxide on the substrate to form a hydrophobic surface (i.e., the interfacial layer 270).

In some embodiments, at operation 10, a rapid thermal process (RTP) is used to form the interfacial layer 270. The RTP may be any suitable process known to the skilled artisan. In some embodiments, at operation 10, the RTP is a thermal oxidation process in which a silicon oxide (SiOx) layer (e.g., the interfacial layer 270) is grown on the top surface of the vertically stacked superlattice structure.

In one or more embodiments, operation 10 further includes depositing an etch stop layer 205 on the interfacial layer 270. In one or more embodiments, the CFET 200 includes an etch stop layer 205 on at least a portion of the interfacial layer 270. In one or more embodiments, the CFET 200 includes an etch stop layer 205 on the entirety of the interfacial layer 270. In some embodiments, the etch stop layer 205 is deposited on a top surface of the interfacial layer 270 using a deposition technique, such as, but not limited to, ALD, CVD, PVD, MBE, MOCVD, spin-on, or other insulating layer deposition techniques known to the skilled artisan.

The etch stop layer 205 may comprise any suitable material known to the skilled artisan. In some embodiments, the etch stop layer 205 includes, but is not limited to, one or more of silicon nitride (SiN), silicon carbonitride (SiCN), or silicon carbooxynitride (SiCON).

Referring again to FIGS. 1A and 2B, in some embodiments, at operation 12, the high-κ dielectric layer 272 is deposited on the interfacial layer 270 with using a deposition technique, such as, but not limited to, ALD, CVD, PVD, MBE, MOCVD, spin-on, or other insulating layer deposition techniques known to the skilled artisan. In some embodiments, at operation 12, the high-κ dielectric layer 272 is conformally deposited on the interfacial layer 270 by ALD.

In some embodiments, the high-κ dielectric layer 272 is conformally deposited on the etch stop layer 205 on the interfacial layer 270 by ALD.

In some embodiments, the high-κ dielectric layer 272 comprises one or more of hafnium oxide (HfOx), hafnium zirconium oxide (HfZrOx), zirconium oxide (ZrOx), nitrogen-doped hafnium oxide (HfOx), nitrogen-doped hafnium zirconium oxide (HfZrOx), and nitrogen-doped zirconium oxide (ZrOx). In some embodiments, the high-κ dielectric layer 272 comprises hafnium oxide (HfOx).

Referring to FIGS. 1A and 2C, in some embodiments, at operation 14, the first p-type dipole layer 274 is deposited on the high-κ dielectric layer 272 using a deposition technique, such as, but not limited to, ALD, CVD, PVD, MBE, MOCVD, spin-on, or other insulating layer deposition techniques known to the skilled artisan. In some embodiments, the first p-type dipole layer 274 comprises one or more of aluminum oxide (AlOx), aluminum nitride (AlNx), or alloys thereof.

In some embodiments, at operation 14, depositing the first p-type dipole layer 274 comprises exposing the substrate 202 (e.g., a top surface of the high-κ dielectric layer 272) to a pulse of an aluminum-containing precursor and a pulse of an oxygen-containing reactant by an atomic layer deposition (ALD) process or a chemical vapor deposition (CVD) process. In some embodiments, at operation 14, depositing the first p-type dipole layer 274 comprises exposing the top surface of the high-κ dielectric layer 272 to a pulse of an aluminum-containing precursor and a pulse of a nitrogen-containing reactant by an atomic layer deposition (ALD) process or a chemical vapor deposition (CVD) process. In some embodiments, the substrate 202 is purged after each pulse.

In some embodiments, the oxygen-containing reactant comprises one or more of oxygen (O₂), ozone (O₃), or water (H₂O).

In some embodiments, the nitrogen-containing reactant comprises one or more of nitrogen (N₂), ammonia (NH₃), hydrazine (N₂H₄), a co-flow of nitrogen radicals (N₂*) and hydrogen radicals (H*), a co-flow of nitrogen radicals (N₂*) and hydrogen (H₂) gas, or a co-flow of nitrogen radicals (N₂*) and deuterium (²H) gas.

In some embodiments, the nitrogen-containing reactant comprises a substituted or unsubstituted alkyl hydrazine. In some embodiments, the alkyl hydrazine comprises in a range of from 1 carbon to 6 carbons. In one or more embodiments, the alkyl hydrazine is t-butyl hydrazine. In some embodiments, the nitrogen-containing reactant comprises a plasma. In some embodiments, the nitrogen-containing reactant comprises ammonia (NH₃).

The first p-type dipole layer 274 may be deposited as a single layer or as a multilayer film. The first p-type dipole layer 274 may be deposited to a predetermined thickness. In some embodiments, the first p-type dipole layer 274 has a thickness in a range of from 3 Angstroms to 25 Angstroms.

Referring to FIGS. 1A and 2D, in some embodiments, at operation 16, a first p-type capping layer 276 is deposited on the first p-type dipole layer 274 using a deposition technique, such as, but not limited to, ALD, CVD, PVD, MBE, MOCVD, spin-on, or other insulating layer deposition techniques known to the skilled artisan. In some embodiments, at operation 16, the first p-type capping layer 276 is conformally deposited on the first p-type dipole layer 274 by ALD. In some embodiments, the first p-type capping layer 276 comprises one or more of silicon (Si), silicon oxide (SiOx), aluminum oxide (AlOx), titanium nitride (TiN), or tantalum nitride (TaN). In some embodiments, the first p-type capping layer 276 has a thickness in a range of from 10 Angstroms to 30 Angstroms.

Referring to FIGS. 1A and 2E, in some embodiments, at operation 18, a first protective layer 278 is deposited on the first portion 202-1 of the substrate 202 using a deposition technique, such as, but not limited to, ALD, CVD, PVD, MBE, MOCVD, spin-on, or other insulating layer deposition techniques known to the skilled artisan. In some embodiments, the first protective layer 278 protects a portion of the first p-type capping layer 276 on the first portion 202-1 of the substrate 202. The first protective layer 278 may include any suitable material known to the skilled artisan. In some embodiments, the first protective layer 278 comprises a hard mask material. In some embodiments, the first protective layer 278 comprises carbon (C). In some embodiments, the first protective layer 278 comprises spin-on carbon (C).

The method 100 includes, at operation 20, selectively etching the vertically stacked superlattice structure 260 to remove the first protective layer 278 from the first portion 202-1 of the substrate 202, and a portion of the first p-type capping layer 276 and a portion of the first p-type dipole layer 274 from the second portion 202-2 of the substrate 202. In one or more embodiments, the method 100 includes selectively etching at operation 20 in order to form multiple threshold voltages (multi-Vₜ) in the CFET 200. FIG. 2F illustrates a bi-cross-sectional view of the substrate 202 of FIG. 2E after etching the vertically stacked superlattice structure 260 at operation 20.

The etching process of operation 20 can be any suitable etching process known to the skilled artisan. In some embodiments, the etching process comprises a wet etch process or a dry etch process. In some embodiments, the etching process comprises a wet etch process. In some embodiments, the wet etch process includes a pre-clean process. In some embodiments, the pre-clean process includes using one or more of ammonium hydroxide (NH₄OH) or water (H₂O). In some embodiments, the water (H₂O) is de-ionized water (DI). In some embodiments, the pre-clean process includes using a ratio of DI:NH₄OH in a range of from 100:1 DI:NH₄OH to 5:1 DI:NH₄OH.

In some embodiments, the pre-clean process includes using a SC-1 solution or a SC-2 solution. In one or more embodiments, the SC-1 solution comprises one or more of ozone, ammonium hydroxide or hydrogen peroxide. In one or more embodiments, the SC-2 solution comprises one or more of hydrochloric aid or hydrogen peroxide. It has advantageously been found that using a SC-1 solution or a SC-2 solution for operation 22 selectively etches the first p-type dipole layer 274 (and other layers thereon) without etching a portion of the interfacial layer 270.

It has been found that selectively etching the vertically stacked superlattice structure 260 at operation 20 to remove the first protective layer 278 from the first portion 202-1 of the substrate 202, and a portion of the first p-type capping layer 276 and a portion of the first p-type dipole layer 274 from the second portion 202-2 of the substrate 202, and increasing a thickness of the dipole layer (e.g., by depositing a second p-type dipole layer 280 at operation 22) advantageously provides a CFET 200 with multi-Vₜ.

Referring to FIGS. 1A and 2G, in some embodiments, at operation 22, a second p-type dipole layer 280 is deposited on the first p-type capping layer 276 in the first portion 202-1, the second portion 202-2, and the third portion 202-3 of the substrate 202 and on the high-κ dielectric layer 272 using a deposition technique, such as, but not limited to, ALD, CVD, PVD, MBE, MOCVD, spin-on, or other insulating layer deposition techniques known to the skilled artisan. In some embodiments, at operation 22, the second p-type dipole layer 280 forms on the first hGAA structure 215, the MDI layer 240, and the second hGAA structure 255. In one or more embodiments, depositing the second p-type dipole layer 280 at operation 22 comprises the same process as depositing the first p-type dipole layer 274 at operation 14.

In some embodiments, the second p-type dipole layer 280 comprises one or more of aluminum oxide (AlOx), aluminum nitride (AlNx), or alloys thereof. The second p-type dipole layer 280 may be deposited as a single layer or as a multilayer film. The second p-type dipole layer 280 may be deposited to a predetermined thickness. In some embodiments, the second p-type dipole layer 280 has a thickness in a range of from 3 Angstroms to 25 Angstroms.

Referring to FIGS. 1A and 2H, in some embodiments, at operation 24, a second p-type capping layer 282 is deposited on the second p-type dipole layer 280 using a deposition technique, such as, but not limited to, ALD, CVD, PVD, MBE, MOCVD, spin-on, or other insulating layer deposition techniques known to the skilled artisan. In some embodiments, at operation 24, the second p-type capping layer 282 is conformally deposited on the second p-type dipole layer 280 by ALD. In some embodiments, the second p-type capping layer 282 comprises one or more of silicon (Si), silicon oxide (SiOx), aluminum oxide (AlOx), titanium nitride (TiN), or tantalum nitride (TaN). In some embodiments, the second p-type capping layer 282 has a thickness in a range of from 30 Angstroms to 70 Angstroms.

In one or more embodiments, at operation 24, the second p-type capping layer 282 fills one or more of the trenches in the vertically stacked superlattice structure 260. In one or more embodiments, at operation 24, the second p-type capping layer 282 fills each of the plurality of vertically extending trenches and each of the plurality of horizontally extending trenches in the vertically stacked superlattice structure 260.

Referring to FIGS. 1A and 2I, in some embodiments, at operation 26, the method 100 comprises selectively etching the vertically stacked superlattice structure 260 to remove a portion of the first p-type capping layer 276, a portion of the first p-type dipole layer 274, a portion of the second p-type capping layer 282, and a portion of the second p-type dipole layer 280 to expose the high-κ dielectric layer 272 on the lower hGAA structure 215. In some embodiments, operation 26 includes the same process as operation 20, and/or operations 30, 34, 40, 44, or 48 (described further below). In one or more embodiments, the method 100 includes selectively etching at operation 26 in order to form multiple threshold voltages (multi-Vₜ) in the CFET. Advantageously, in one or more embodiments, operation 26 selectively etches the vertically stacked superlattice structure 260 to remove the first p-type capping layer 276, the first p-type dipole layer 274, the second p-type capping layer 282, and the second p-type dipole layer 280 from the upper hGAA 255. Accordingly, operation 26 is a selective etch process relative to the high-κ dielectric layer 272.

In one or more embodiments, the portion of the second p-type capping layer 282 that is removed is the portion that is deposited on top of the second p-type dipole layer 280, and in the plurality of vertically extending trenches extending from the top surface of the second or upper hGAA 255 to the MDI layer 240. Stated differently, the material of the second p-type capping layer 282 that fills the plurality of vertically extending trenches and the plurality of horizontally extending trenches in the first or lower hGAA 215 remains after etching at operation 26.

Referring to FIGS. 1A and 2J, in some embodiments, at operation 28, a first n-type dipole layer 290 on the exposed high-κ dielectric layer 272 on the second hGAA structure 255 using a deposition technique, such as, but not limited to, ALD, CVD, PVD, MBE, MOCVD, spin-on, or other insulating layer deposition techniques known to the skilled artisan. In some embodiments, the first n-type dipole layer 290 comprises one or more of lanthanum oxide (LaOx), lanthanum nitride (LaNx), or alloys thereof.

In some embodiments, at operation 28, depositing the first n-type dipole layer 290 comprises exposing the substrate 202 (e.g., a top surface of the exposed high-κ dielectric layer 272) to a pulse of a lanthanum-containing precursor and a pulse of an oxygen-containing reactant by an atomic layer deposition (ALD) process or a chemical vapor deposition (CVD) process. In some embodiments, at operation 34, depositing the first n-type dipole layer 290 comprises exposing the top surface of the exposed high-κ dielectric layer 272 to a pulse of a lanthanum-containing precursor and a pulse of a nitrogen-containing reactant by an atomic layer deposition (ALD) process or a chemical vapor deposition (CVD) process. In some embodiments, the substrate 202 is purged after each pulse.

In some embodiments, the oxygen-containing reactant comprises one or more of oxygen (O₂), ozone (O₃), or water (H₂O).

In some embodiments, the nitrogen-containing reactant comprises one or more of nitrogen (N₂), ammonia (NH₃), hydrazine (N₂H₄), a co-flow of nitrogen radicals (N₂*) and hydrogen radicals (H*), a co-flow of nitrogen radicals (N₂*) and hydrogen (H₂) gas, or a co-flow of nitrogen radicals (N₂*) and deuterium (²H) gas.

In some embodiments, the nitrogen-containing reactant comprises a substituted or unsubstituted alkyl hydrazine. In some embodiments, the alkyl hydrazine comprises in a range of from 1 carbon to 6 carbons. In one or more embodiments, the alkyl hydrazine is t-butyl hydrazine. In some embodiments, the nitrogen-containing reactant comprises a plasma. In some embodiments, the nitrogen-containing reactant comprises ammonia (NH₃).

The first n-type dipole layer 290 may be deposited as a single layer or as a multilayer film. The first n-type dipole layer 290 may be deposited to a predetermined thickness. In some embodiments, the first n-type dipole layer 290 has a thickness in a range of from 3 Angstroms to 25 Angstroms.

Referring to FIGS. 1A and 2K, in some embodiments, at operation 30, a first n-type capping layer 292 is deposited on the first n-type dipole layer 290 using a deposition technique, such as, but not limited to, ALD, CVD, PVD, MBE, MOCVD, spin-on, or other insulating layer deposition techniques known to the skilled artisan. In some embodiments, at operation 30, the first n-type capping layer 292 is conformally deposited on the first n-type dipole layer 290 (on the second hGAA structure 255) by ALD. In some embodiments, the first n-type capping layer 292 comprises one or more of silicon (Si), silicon oxide (SiOx), aluminum oxide (AlOx), titanium nitride (TIN), or tantalum nitride (TaN). In some embodiments, the first n-type capping layer 292 has a thickness in a range of from 10 Angstroms to 30 Angstroms.

Referring to FIGS. 1A and 2L, in some embodiments, at operation 32, a second protective layer 284 is deposited on the first portion 202-1 of the substrate 202 using a deposition technique, such as, but not limited to, ALD, CVD, PVD, MBE, MOCVD, spin-on, or other insulating layer deposition techniques known to the skilled artisan. In some embodiments, the second protective layer 284 protects the first n-type capping layer 292, the first n-type dipole layer 290, and layers beneath the first n-type dipole layer 290. The second protective layer 284 may include any suitable material known to the skilled artisan. In some embodiments, the second protective layer 284 comprises a hard mask material. In some embodiments, the second protective layer 284 comprises carbon (C). In some embodiments, the second protective layer 284 comprises spin-on carbon (C).

Referring to FIGS. 1A and 2M, in some embodiments, at operation 34, the method 100 comprises selectively etching the vertically stacked superlattice structure 260 to remove the second protective layer 284 to expose the first portion 202-1, and remove a portion of the first n-type capping layer 292 and a portion of the first n-type dipole layer 290 from the second portion 202-2 and third portion 202-3 of the substrate 202. In some embodiments, operation 30 includes the same process as operation 20, 26, and/or 40, 44, or 48 (described further below). In one or more embodiments, the method 100 includes selectively etching at operation 34 in order to form multiple threshold voltages (multi-Vₜ) in the CFET 200.

Referring to FIGS. 1A and 2N, in some embodiments, at operation 36, a second n-type dipole layer 296 is deposited on the first portion 202-1, the second portion 202-2, and the third portion 202-2 using a deposition technique, such as, but not limited to, ALD, CVD, PVD, MBE, MOCVD, spin-on, or other insulating layer deposition techniques known to the skilled artisan. In some embodiments, at operation 36, the second n-type dipole layer 296 is conformally deposited on the second hGAA structure 255 by ALD. In one or more embodiments, depositing the second n-type dipole layer 296 at operation 36 comprises the same process as depositing the first n-type dipole layer 290 at operation 28.

In some embodiments, the second n-type dipole layer 296 comprises one or more of lanthanum oxide (LaOx), lanthanum nitride (LaNx), or alloys thereof. The second n-type dipole layer 296 may be deposited as a single layer or as a multilayer film. The second n-type dipole layer 296 may be deposited to a predetermined thickness. In some embodiments, the second n-type dipole layer 296 has a thickness in a range of from 3 Angstroms to 25 Angstroms.

Referring to FIGS. 1A and 2O, in some embodiments, at operation 38, a second n-type capping layer 298 is deposited on the second n-type dipole layer 296 using a deposition technique, such as, but not limited to, ALD, CVD, PVD, MBE, MOCVD, spin-on, or other insulating layer deposition techniques known to the skilled artisan. In some embodiments, at operation 38, the second n-type capping layer 298 is conformally deposited on the second n-type dipole layer 296 by ALD. In some embodiments, the second n-type capping layer 298 comprises one or more of silicon (Si), silicon oxide (SiOx), aluminum oxide (AlOx), titanium nitride (TiN), or tantalum nitride (TaN). In some embodiments, the second n-type capping layer 298 has a thickness in a range of from 30 Angstroms to 70 Angstroms.

In one or more embodiments, at operation 38, the second n-type capping layer 298 fills one or more of the trenches in the vertically stacked superlattice structure 260. In one or more embodiments, at operation 38, the second n-type capping layer 298 fills each of the plurality of vertically extending trenches and each of the plurality of horizontally extending trenches in the vertically stacked superlattice structure 260. More particularly, in one or more embodiments, the second n-type capping layer 298 fills each of the plurality of vertically extending trenches and each of the plurality of horizontally extending trenches in the second or upper hGAA 255 to the MDI layer 240.

Referring to FIGS. 1A and 2P, in some embodiments, at operation 40, the method 100 includes etching the vertically stacked superlattice structure 260 to remove a portion of the second n-type capping layer 298 and a portion of the second n-type dipole layer 296 from the first portion 202-1, the second portion 202-2, and the third portion 202-3 of the substrate 202.

In one or more embodiments, at operation 40, the vertically stacked superlattice structure 260 is etched to expose a top surface of the etch stop layer 205.

In one or more embodiments, the portion of the second n-type capping layer 298 that is removed is the portion that is deposited on top of the second n-type dipole layer 296. Stated differently, the material of the second n-type capping layer 298 that fills the plurality of vertically extending trenches and the plurality of horizontally extending trenches up to a bottom surface of the etch stop layer 205 is not removed.

In one or more embodiments, after etching at operation 40, the plurality of vertically extending trenches and the plurality of horizontally extending trenches are filled with the material of the second n-type capping layer 298 in the second or upper hGAA 255, and the plurality of vertically extending trenches and the plurality of horizontally extending trenches are filled with the material of the second p-type capping layer 282 in the first or lower hGAA 215.

Referring to FIGS. 1A and 2Q, in some embodiments, at operation 42, a third protective layer 294 is deposited on the first portion 202-1 and the second portion 202-2 of the substrate 202 using a deposition technique, such as, but not limited to, ALD, CVD, PVD, MBE, MOCVD, spin-on, or other insulating layer deposition techniques known to the skilled artisan. In some embodiments, the top surface of the etch stop layer 205 remains exposed in the third portion 202-3 of the substrate 202.

In some embodiments, the third protective layer 294 protects the second n-type capping layer 298, the second n-type dipole layer 296, the first n-type capping layer 292, the first n-type dipole layer 290, and layers beneath the first n-type dipole layer 290. The third protective layer 294 may include any suitable material known to the skilled artisan. In some embodiments, the third protective layer 294 comprises a hard mask material. In some embodiments, the third protective layer 294 comprises carbon (C). In some embodiments, the third protective layer 294 comprises spin-on carbon (C).

Referring to FIGS. 1A and 2R, at operation 44, the method 100 includes selectively etching the vertically stacked superlattice structure 260 to remove the third protective layer 294, and a portion of the first n-type capping layer 292 and a portion of the first n-type dipole layer 290 from the second portion 202-2 of the substrate 202, and to expose the high-κ dielectric layer 272 on each of the first hGAA structure 215 and the second hGAA structure 255 in the third portion 202-3. In one or more embodiments, the method 100 includes selectively etching at operation 44 in order to form multiple threshold voltages (multi-Vₜ) in the CFET 200. In FIG. 2R, the top surface of the etch stop layer 205 is exposed in the first portion 202-1, the second portion 202-2, and the third portion 202-3 of the substrate 202.

Referring to FIGS. 1A and 2S, in some embodiments, at operation 46, the method 100 includes annealing the substrate 202 (denoted by arrows 302) at a temperature of less than or equal to 1000° C. to drive atoms from each of the first p-type dipole layer 274, the second p-type dipole layer 280, the first n-type dipole layer 290, and the second n-type dipole layer 296 into the high-κ dielectric layer 272 to form an annealed high-κ dielectric layer 272′ (shown in FIG. 2T).

In some embodiments, at operation 46, the method 100 comprises annealing the substrate 202 at a temperature of less than or equal to 950° C. In some embodiments, the temperature is in a range of from 500° C. to 1000° C., including in a range of from 600° C. to 1000° C., in a range of from 700° C. to 1000° C., in a range of from 750° C. to 950° C., or in a range of from 800° C. to 900° C.

Without intending to be bound by theory, it is thought that annealing the substrate 202 according to operation 46 drives an increased number of atoms from the dipole layer(s) (e.g., the first p-type dipole layer 274, the second p-type dipole layer 280, the first n-type dipole layer 290, and/or the second n-type dipole layer 296) into the interface of the interfacial layer 270 and the high-κ dielectric layer 272, as compared to methods where annealing does not occur. In one or more embodiments, annealing the substrate 202 at operation 46 includes a rapid thermal process (RTP). The RTP may be any suitable process known to the skilled artisan. Without intending to be bound by theory, when, at operation 46, the method 100 comprises annealing the substrate 202 at a temperature of less than or equal to 1000° C. to drive atoms from the dipole layer(s) into the interface of the interfacial layer 270 and the high-κ dielectric layer 272, such that the interface of the interfacial layer 270 and the high-κ dielectric layer 272 comprises properties of the dipole layer(s).

Referring to FIGS. 1A and 2T, in some embodiments, at operation 48, the method 100 includes etching the vertically stacked superlattice structure 260 to remove each of the first p-type dipole layer 274, the first p-type capping layer 276, the second p-type dipole layer 280, the second p-type capping layer 282, the first n-type dipole layer 290, the first n-type capping layer 292, the second n-type dipole layer 296, and the second n-type capping layer 298. In FIG. 2T, the top surface of the etch stop layer 205 is exposed in the first portion 202-1, the second portion 202-2, and the third portion 202-3 of the substrate 202.

After operation 48, the method 100 can include any post-processing operations for semiconductor manufacturing known to the skilled artisan.

In one or more embodiments, the CFET 200 may include any suitable number of different dipole layer thicknesses and multiple threshold voltages (multi-Vₜ). In one or more embodiments, the CFET 200 includes two different dipole layer thicknesses and two multiple threshold voltages (multi-Vₜ). In one or more embodiments, the CFET 200 includes three different dipole layer thicknesses and three multiple threshold voltages (multi-Vₜ). In one or more embodiments, the CFET 200 includes four different dipole layer thicknesses and four multiple threshold voltages (multi-Vₜ).

Further embodiments of the disclosure are directed to electronic devices having a plurality of CFET regions. In one or more embodiments, the electronic device comprises the CFET 200 formed by method 100.

In some embodiments, the electronic device (e.g., CFET 200) comprises a first complementary field-effect transistor (CFET) region having a first threshold voltage (Vₜ); a second CFET region having a second Vi; and a third CFET region having a third Vi, each of the first CFET region, the second CFET region, and the third CFET region formed on a vertically stacked superlattice structure 260 on a substrate 202, the vertically stacked superlattice structure 260 comprising a first horizontal gate-all-around (hGAA) structure 215 (e.g., a positive metal-oxide-semiconductor (PMOS) transistor) on a top surface 203 of the substrate 202, a MDI layer 240 on a top surface 225 of the first hGAA structure 215, and a second hGAA structure 255 (e.g., a negative metal-oxide-semiconductor (NMOS) transistor) on a top surface 245 of the MDI layer 240, and an interfacial layer 270 on each of the first hGAA structure 215, the MDI layer 240, and the second hGAA structure 255.

In some embodiments, the first CFET region comprises a hafnium oxide (HfOx) layer 272 on the interfacial layer 270, a first p-type dipole layer 274 on the hafnium oxide (HfOx) layer 272, and a first p-type capping layer 276 on the first p-type dipole layer 274.

In some embodiments, the second CFET region comprises the hafnium oxide (HfOx) layer 272 on the interfacial layer 270, the first p-type dipole layer 274 on the hafnium oxide (HfOx) layer 272, the first p-type capping layer 276 on the first p-type dipole layer 274, a second p-type dipole layer 280 on a first exposed portion of the hafnium oxide (HfOx) layer 272, and a second p-type capping layer 282 on the second p-type dipole layer 280.

In some embodiments, the third CFET region comprises the hafnium oxide (HfOx) layer 272 on the interfacial layer 270, the first p-type dipole layer 274 on the hafnium oxide (HfOx) layer 272, the first p-type capping layer 276 on the first p-type dipole layer 274, the second p-type dipole layer 280 on the first exposed portion of the hafnium oxide (HfOx) layer 272, the second p-type capping layer 282 on the second p-type dipole layer 280, a first n-type dipole layer 290 on the exposed high-κ dielectric layer 272 on the second hGAA structure 255, a first n-type capping layer 292 on the first n-type dipole layer 290, a second n-type dipole layer 296 on the second hGAA structure 255, and a second n-type capping layer 298 on the second n-type dipole layer 296.

In one or more embodiments, each of the first p-type dipole layer 274 and the second p-type dipole layer 280 independently comprise one or more of aluminum oxide (AlOx), aluminum nitride (AlNx), or alloys thereof. In some embodiments, each of the first n-type dipole layer 290 and the second n-type dipole layer 296 independently comprise one or more of lanthanum oxide (LaOx), lanthanum nitride (LaNx), or alloys thereof.

In some embodiments, each of the first p-type capping layer 276, the second p-type capping layer 282, the first n-type capping layer 292, and the second n-type capping layer 298 independently comprise one or more of silicon (Si), silicon oxide (SiOx), aluminum oxide (AlOx), titanium nitride (TiN), or tantalum nitride (TaN).

Additional embodiments of the disclosure are directed to processing tools (i.e., a cluster tool) for performing the methods and the CFETs described. In one or more embodiments, the cluster tool comprises an integrated processing system such that the operations of method 100 are performed without a vacuum break. In one or more embodiments, there is a vacuum break in between at least one of the operations of method 100.

The particular arrangement of process chambers and components can be varied depending on the cluster tool and should not be taken as limiting the scope of the disclosure.

Embodiments of the disclosure are directed to a non-transitory computer readable medium. In one or more embodiments, the non-transitory computer readable medium includes instructions that, when executed by a controller of a processing chamber, causes the processing chamber to perform the operations of any of the methods described herein. In one or more embodiments, the controller causes the processing chamber to perform the operations of method 100.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1-20. (canceled)

21. A method of forming a complementary field-effect transistor (CFET), the method comprising:
forming a first complementary field-effect transistor (CFET) region having a first threshold voltage (Vₜ);
forming a second CFET region having a second Vₜ, the second CFET region adjacent the first CFET region; and
forming a third CFET region having a third Vₜ, the third CFET region adjacent the second CFET region,
each of the first CFET region, the second CFET region, and the third CFET region formed on a high-κ dielectric layer on an interfacial layer on a vertically stacked superlattice structure on a substrate, the vertically stacked superlattice structure comprising a second horizontal gate-all-around (hGAA) structure on a middle dielectric isolation (MDI) layer, on a first hGAA structure.

22. The method of claim 21, wherein forming the first CFET region comprises:
depositing a first p-type dipole layer on the high-κ dielectric layer;
depositing a first p-type capping layer on the first p-type dipole layer;
depositing a first protective layer on a first portion of the substrate; and
etching the vertically stacked superlattice structure to remove the first protective layer, and a portion of the first p-type capping layer and a portion of the first p-type dipole layer from a second portion of the substrate.

23. The method of claim 22, wherein forming the second CFET region comprises:
depositing a second p-type dipole layer on the first portion, the second portion, and a third portion of the substrate, the second p-type dipole layer forming on the first hGAA structure, the MDI layer, and the second hGAA structure;
depositing a second p-type capping layer on the second p-type dipole layer, the second p-type capping layer filling trenches in the vertically stacked superlattice structure; and
etching the vertically stacked superlattice structure to remove a portion of the first p-type capping layer, a portion of the first p-type dipole layer, a portion of the second p-type capping layer, and a portion of the second p-type dipole layer to expose the high-κ dielectric layer on the second hGAA structure.

24. The method of claim 23, wherein forming the third CFET region comprises:
depositing a first n-type dipole layer on the exposed high-κ dielectric layer on the second hGAA structure;
depositing a first n-type capping layer on the first n-type dipole layer;
depositing a second protective layer on the first portion of the substrate; and
etching the vertically stacked superlattice structure to remove the second protective layer to expose the first portion of the first n-type capping layer, and remove a portion of the first n-type capping layer and a portion of the first n-type dipole layer from the second portion and third portion of the substrate.

25. The method of claim 24, wherein forming the third CFET region further comprises:
depositing a second n-type dipole layer on the first portion, the second portion, and the third portion of the substrate, the second n-type dipole layer forming on the second hGAA structure;
depositing a second n-type capping layer on the second n-type dipole layer, the second n-type capping layer filling the trenches in the vertically stacked superlattice structure; and
etching the vertically stacked superlattice structure to remove a portion of the second n-type capping layer and a portion of the second n-type dipole layer from the first portion, the second portion, and the third portion of the substrate.

26. The method of claim 25, further comprising depositing a third protective layer on the first portion and the second portion of the substrate.

27. The method of claim 26, further comprising etching the vertically stacked superlattice structure to remove the third protective layer, and a portion of the first n-type capping layer and a portion of the first n-type dipole layer from the second portion of the substrate, and to expose the high-κ dielectric layer on each of the first hGAA structure and the second hGAA structure.

28. The method of claim 27, further comprising annealing the substrate to form an annealed high-κ dielectric layer.

29. The method of claim 28, further comprising etching the vertically stacked superlattice structure after annealing.

30. The method of claim 29, wherein etching the vertically stacked superlattice structure after annealing is configured to remove each of the first p-type dipole layer, the first p-type capping layer, the second p-type dipole layer, the second p-type capping layer, the first n-type dipole layer, the first n-type capping layer, the second n-type dipole layer, and the second p-type capping layer.

31. The method of claim 21, wherein the first hGAA structure is a positive metal-oxide-semiconductor (PMOS) transistor, and the second hGAA structure is a negative metal-oxide-semiconductor (NMOS) transistor.

32. The method of claim 23, wherein each of the first p-type dipole layer and the second p-type dipole layer independently comprise one or more of aluminum oxide (AlOx), aluminum nitride (AlNx), or alloys thereof, and each of the first p-type capping layer and the second p-type capping layer independently comprise one or more of silicon (Si), silicon oxide (SiOx), aluminum oxide (AlOx), titanium nitride (TiN), or tantalum nitride (TaN).

33. The method of claim 25, wherein each of the first n-type dipole layer and the second n-type dipole layer independently comprise one or more of lanthanum oxide (LaOx), lanthanum nitride (LaNx), or alloys thereof, and each of the first n-type capping layer and the second n-type capping layer independently comprise one or more of silicon (Si), silicon oxide (SiOx), aluminum oxide (AlOx), titanium nitride (TiN), or tantalum nitride (TaN).

34. The method of claim 26, wherein each of the first protective layer, the second protective layer, and the third protective layer independently comprise a hard mask material.

35. An electronic device comprising:
a first complementary field-effect transistor (CFET) region having a first threshold voltage (Vₜ);
a second CFET region having a second Vi; and
a third CFET region having a third Vₜ,
each of the first CFET region, the second CFET region, and the third CFET region formed on an interfacial layer on a vertically stacked superlattice structure on a substrate, the vertically stacked superlattice structure comprising a second horizontal gate-all-around (hGAA) structure on a middle dielectric isolation (MDI) layer, on a first hGAA structure.

36. The electronic device of claim 35, wherein the first CFET region comprises a high-κ dielectric layer on the interfacial layer, a first p-type dipole layer on the high-κ dielectric layer, and a first p-type capping layer on the first p-type dipole layer.

37. The electronic device of claim 36, wherein the second CFET region comprises the high-κ dielectric layer on the interfacial layer, the first p-type dipole layer on the high-κ dielectric layer, the first p-type capping layer on the first p-type dipole layer, a second p-type dipole layer, and a second p-type capping layer on the second p-type dipole layer.

38. The electronic device of claim 37, wherein the third CFET region comprises the high-k dielectric layer on the interfacial layer, the first p-type dipole layer on the high-κ dielectric layer, the first p-type capping layer on the first p-type dipole layer, the second p-type dipole layer, the second p-type capping layer on the second p-type dipole layer, a first n-type dipole layer on an exposed portion of the high-κ dielectric layer on the second hGAA structure, a first n-type capping layer on the first n-type dipole layer, a second n-type dipole layer on the second hGAA structure, and a second n-type capping layer on the second n-type dipole layer.

39. The electronic device of claim 38, wherein each of the first p-type dipole layer and the second p-type dipole layer independently comprise one or more of aluminum oxide (AlOx), aluminum nitride (AlNx), or alloys thereof, and each of the first n-type dipole layer and the second n-type dipole layer independently comprise one or more of lanthanum oxide (LaOx), lanthanum nitride (LaNx), or alloys thereof.

40. The electronic device of claim 39, wherein each of the first p-type capping layer, the second p-type capping layer, the first n-type capping layer, and the second n-type capping layer independently comprise one or more of silicon (Si), silicon oxide (SiOx), aluminum oxide (AlOx), titanium nitride (TiN), or tantalum nitride (TaN).
